(19) United States
(12) Patent Application Publication
(10) Pub. No.: US 2026/0223653 A1
(43) Pub. Date: Jul. 30, 2026

(54) DAMASCENE PROCESSES

(71) Applicant: Taiwan Semiconductor Manufacturing Company, Ltd., Hsinchu (TW)

(72) Inventors: Chien-Han Chen, Nantou County (TW); Shih-Yu Chang, Yunlin County (TW); Chien-Chih Chiu, Xinying City (TW)

(73) Assignee: Taiwan Semiconductor Manufacturing Company, Ltd., Hsinchu (TW)

(21) Appl. No.: 19/036,686

(22) Filed: Jan. 24, 2025

(51) Int. Cl. H01L 21/768; H01L 23/522; H01L 23/528; H01L 23/532

(52) U.S. Cl. CPC H10W 20/084; H10W 20/033; H10W 20/038; H10W 20/057; H10W 20/089; H10W 20/42; H10W 20/425; H10W 20/435; H10W 20/495; H10W 20/498; H10W 20/0886

(57) ABSTRACT

Provided are semiconductor structures and methods for fabricating such structures. A method includes forming a conductive via over a substrate; forming a dielectric layer over the conductive via and the substrate; patterning a mask over the dielectric layer; performing an etch process to etch the dielectric layer through the mask to form a trench over the conductive via, wherein the trench extends to a trench bottom formed by the dielectric layer, and wherein the trench bottom intersects the conductive via; and forming a conductive structure in the trench.

### BACKGROUND

Semiconductor devices use an interconnect structure, which includes metal lines and contacts/vias, to provide connection between active devices and/or passive devices with external contacts. Typically, the metal patterns of different metallization layers are electrically interconnected by vias. Semiconductor devices with interconnect circuits, according to current technology, may comprise eight or more levels of metallization to satisfy device connection and geometry requirements. There are challenges in forming interconnect for advanced device technologies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIGS. 2-12 are cross-sectional schematic views of a portion of a semiconductor structure during sequential stages of the method of FIG. 1, in accordance with some embodiments.

FIG. 13 is a cross-sectional schematic view of a portion of a semiconductor structure at the same fabrication stage as FIG. 12, in accordance with some embodiments.

FIG. 14 is a flow chart illustrating a method, in accordance with some embodiments.

FIGS. 15-23 are cross-sectional schematic views of a portion of a semiconductor structure during sequential stages of the method of FIG. 14, in accordance with some embodiments.

FIG. 24 is a cross-sectional schematic view of two portions of a semiconductor structure at the same fabrication stage as FIG. 23, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments provided herein provide for forming conductive interconnects. In particular, embodiments described herein may provide a high performance design for trench encapsulation in via architecture on back-end-of-line (BEOL) single damascene processes.

At increased scaling, extremely small dimensions and pitches have caused many bottlenecks in the dual-damascene process. For example, issues such as pulling between the via RC and bridge window in the self-alignment via (SAV) process, pits performance in copper metallization, and challenges in CMP polish window persist. As a result, back-end of line (BEoL) single-damascene is gradually replacing dual-damascene as preferred processing.

As the trench and via in single damascene are fabricated separately, several major issues may arise: (1) performance loss due to the high-k etch-stop layer in trench and via interface, and (2) an increase in resistance due to the small trench to via contact area. These factors may contribute to additional resistive-capacitive (RC) delay penalties during the process change. To reduce resistance, one approach is to taper the via to increase the contact area with the trench to via. However, tapering the via may introduce additional risks of leakage.

Dual-damascene processing adopts trench/via all-in-one etch, and copper gap-filling is also filled at the same time. Therefore, the advantage is an efficient and simple flow, and a reduction in capacitance due to fewer heterogeneous materials. Because of these advantages, copper dual-damascene has been the main manufacturing method for back-end interconnects in the past decade. However, with the shrinking dimension, dual-damascene has encountered many barriers. Therefore, many semiconductor manufacturers are gradually seeking opportunities to interconnect single-damascene processing.

Embodiments herein increase the contact area between the lower conductive via and the upper conductive trench. To do so, embodiment herein avoid use of an etch stop layer to define the trench bottom of the upper conductive trench. By removing the etch stop layer from the upper trench bottom, several benefits are achieved: (1) the high K interface is removed to reduce parasitic capacitance, and (2) the contact area between the conductive trench and conductive via is increased to reduce capacitive resistance (Rc).

In certain embodiments, copper is used for trench gap-filling. The copper may encapsulate the gap-filling materials (Ru/W/Mo) for conductive vias.

In certain embodiments, the upper surface of the conductive via is rounded, further increasing the contact area between the conductive via and the conductive trench.

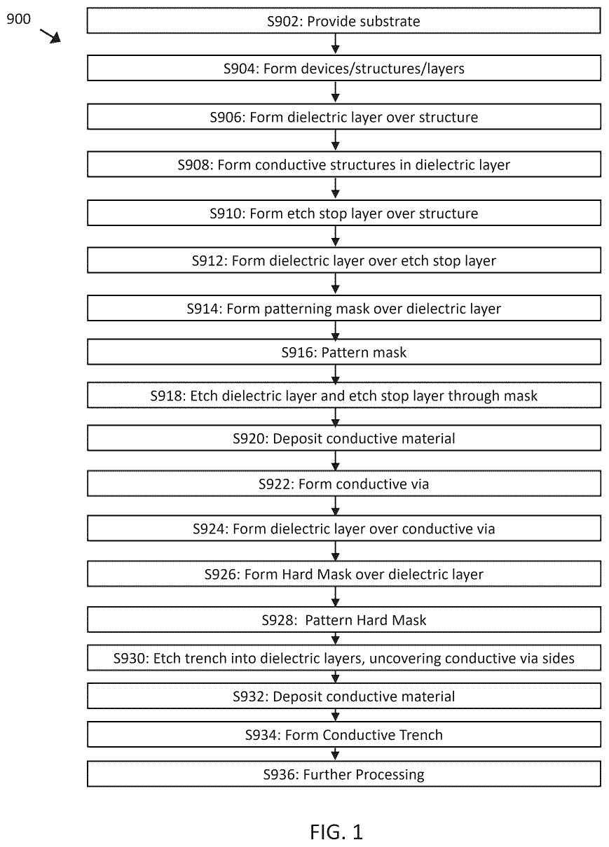

Referring to FIG. 1, a method 900 for forming a semiconductor structure 100 is illustrated in a flow chart, according to various aspects of the present disclosure.

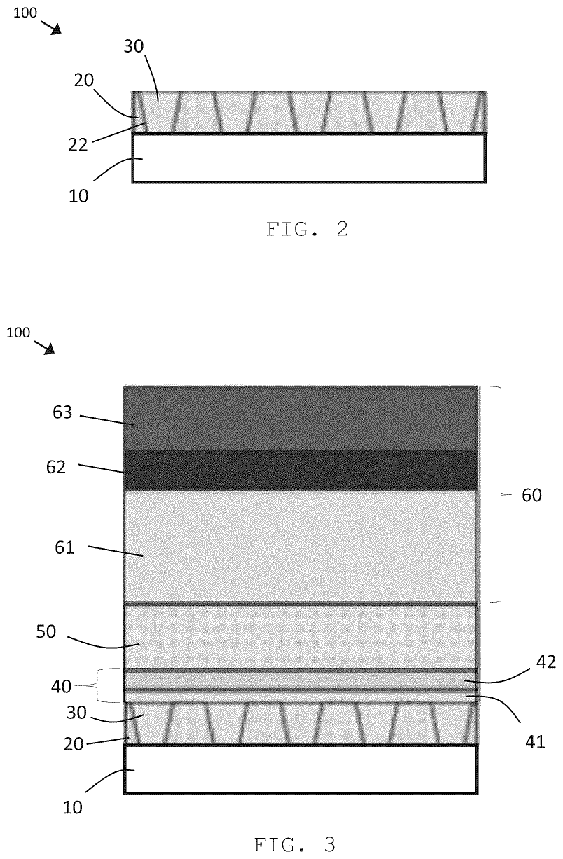

FIG. 1 is described in conjunction with FIGS. 2-12, which illustrate a semiconductor device or structure 100 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with other method embodiments and exemplary devices discussed herein, it is understood that parts of the semiconductor structure 100 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S902, the method 900 (FIG. 1) provides a substrate 10, as shown in FIG. 2. In some embodiments, the substrate 10 may be a semiconductor substrate such as a silicon (Si) substrate. The substrate 10 may include various layers, including conductive or insulating layers formed on a semiconductor substrate. The substrate 10 may include various doping configurations depending on design requirements as is known in the art. For example, different doping profiles (e.g., p-well, n-well) may be formed on the substrate 10 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 10 includes a single crystalline semiconductor layer on at least its surface portion. The substrate 10 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 10 may include a compound semiconductor and/or an alloy semiconductor. In the illustrated embodiment, the substrate 10 is made of crystalline Si.

At operation S904, the method 900 (FIG. 1) may form active devices, such as transistors, etc., passive devices, such as resistors and others, interconnect structures, and insulating layers on and/or in substrate 10.

At operation S906, the method 900 (FIG. 1) may form a dielectric layer 20 over the substrate 10. The dielectric layer 20 may be an interlayer dielectric (ILD) layer or an intermetal dielectric (IMD) layer. In some embodiments, the dielectric layer 20 is a low-K dielectric layer. For example, the dielectric layer 20 may have a K value of from 2 to 3.

At operation S908, the method 900 (FIG. 1) forms conductive structures 30 in the dielectric layer 20. For example, in some embodiments, a hard mask layer (not shown) may be formed on dielectric layer 20 and patterned to assist the formation of trenches 22. The hard mask layer may be made of SiN, SiON, or a combination thereof. The hard mask layer may also be a metal hard mask.

Trenches 22 are then etched into the dielectric layer 20. Further, the conductive structures 30, such as contacts or conductive plugs, are formed in the trenches 22. For example, the conductive structures 30 may be formed by depositing a metal or metals, such as copper, ruthenium, and/or tungsten, or other suitable metals. A chemical-mechanical planarization (CMP) process may be used to planarize the structure 100, removing an overburden portion of the metals of the conductive structures 30, and removing the hard mask layer if still present, to define the conductive structures 30 in the trenches 22.

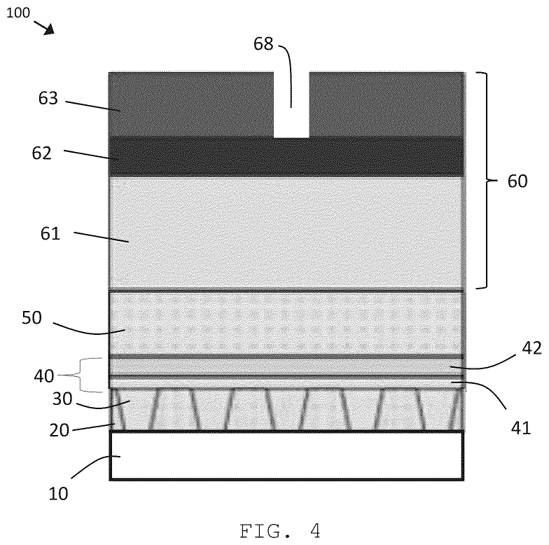

At operation S910, the method 900 (FIG. 1) forms an etch stop layer 40 over the dielectric layer 20 and conductive structures 30, as shown in FIG. 3. For example, operation S910 may include forming a first etch stop layer 41 over the dielectric layer 20 and conductive structures 30. In certain embodiments, the first etch stop layer 41 may be formed from or includes layers of AlON, AlOx, AlON, SiCN, and/or other suitable materials. Also, operation S910 may include forming a second etch stop layer 42 over the first etch stop layer 41. In certain embodiments, the second etch stop layer 42 may be formed from or include layers of SiC, SiOx, SiOC, SiON, and/or other suitable materials.

At operation S912, the method 900 (FIG. 1) forms a dielectric layer 50 over the etch stop layer 40, as shown in FIG. 3. In certain embodiments, the dielectric layer 50 is a low-K dielectric layer. For example, the dielectric layer 50 may have a K value of from 2 to 3.

At operation S914, the method 900 (FIG. 1) forms a patterning mask 60 over the dielectric layer 50, as shown in FIG. 3.

The patterning mask 60 may include multiple layers, such as a bottom layer 61, a middle layer 62, and a top layer 63. In some embodiments, the bottom layer 61 is a bottom anti-reflective coating (BARC). The BARC may provide for absorption of radiation incident to the substrate during photolithography processes, including exposure of an overlying photoresist layer. In some embodiments, the middle layer 62 includes a reflective multilayer structure. In some embodiments, the top layer 63 is a photosensitive mask (e.g., photoresist).

The photoresist may be positive-tone or negative-tone resist. In an embodiment, the photoresist is chemical amplified photoresist (CAR). The photoresist may include a polymer, a photoacid generator (PAG), which provides the solubility change to the developer, a solvent, and/or other suitable compositions. The photoresist may be formed by processes such as coating (e.g., spin-on coating) and soft baking.

At operation S916, the method 900 (FIG. 1) patterns the photoresist layer 63, as shown in FIG. 4, to form an opening 68. For example, the method may use various and/or varying wavelengths of radiation to expose the energy-sensitive photoresist layer. In an embodiment, the mask is irradiated using ultraviolet (UV) radiation or extreme ultraviolet (EUV) radiation. The radiation beam may additionally or alternatively include other radiation beams such as ion beam, x-ray, extreme ultraviolet, deep ultraviolet, and other proper radiation energy. In an example, the photoresist includes photo-acid generator (PAG) that generates acid during the exposure process thus changing the solubility of the exposed/non-exposed material. Lithography processes include immersion lithography, photolithography, optical lithography and/or other patterning methods which may transfer a pattern onto the photosensitive layer. Patterning may further include a post-exposure bake (PEB) process. During the baking process, the photoresist layer is provided at an elevated temperature. This may allow more acid to be generated from the photo-generated acids through a chemical amplification process. Further, patterning may include developing the photoresist layer. The developing may form a patterned photoresist layer including a plurality of masking elements or features. During the developing process, a developing solution is applied to the photoresist layer. In one embodiment, the photoresist material that was exposed to the radiation is removed by the developing solution (developer). However, implementing a negative-tone resist is also possible. The developer or developing solution may be a positive tone developer or negative tone developer. One exemplary developer is aqueous tetramethylammonium hydroxide (TMAH).

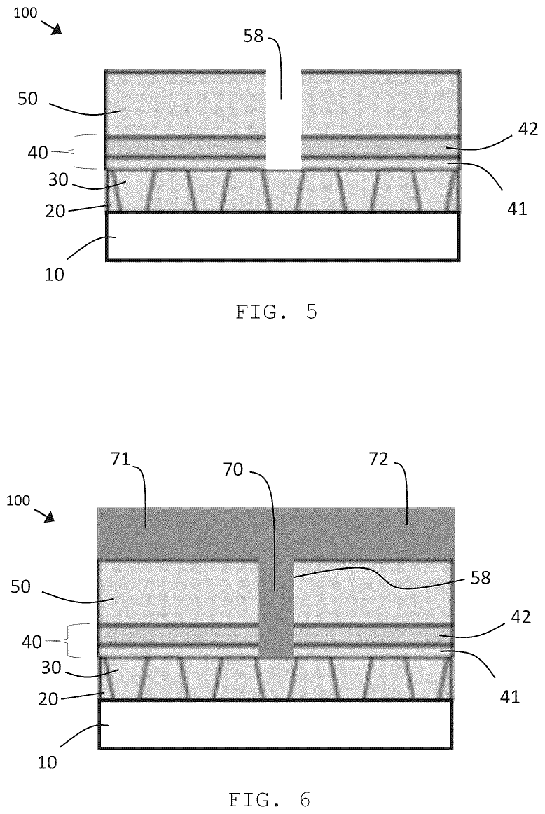

At operation S918, the method 900 (FIG. 1) performs an etch process to etch the structure 100 through the opening 68 to form an opening 58 through the dielectric layer 50 and into the etch stop layer 40, as shown in FIG. 5. For example, the etch process may extend through the etch stop layer 40 such that the opening 58 contacts a selected conductive structure 30. The etch process may remove the mask 60, or the mask may be removed after the etch process.

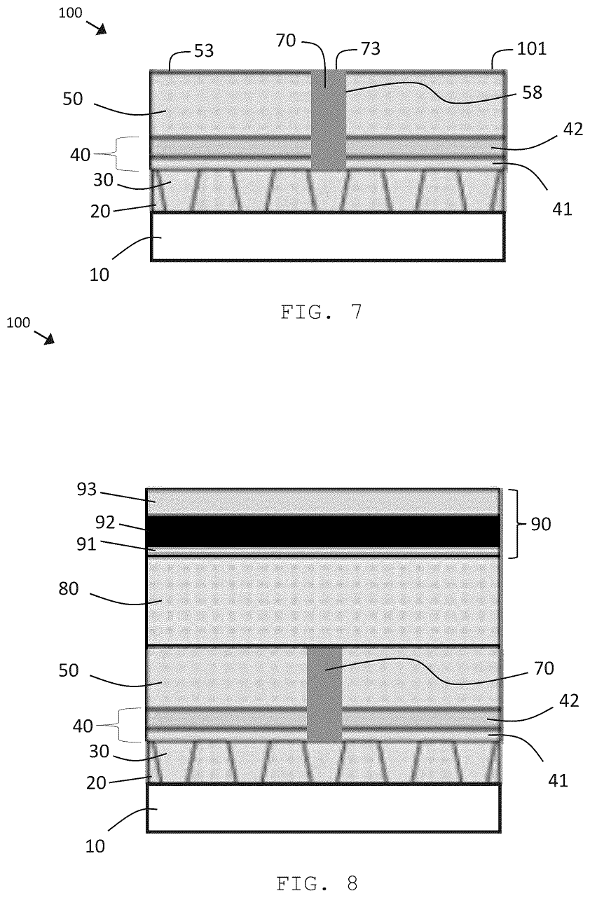

At operation S920, the method 900 (FIG. 1) deposits a conductive material 71 to fill the opening 58 as shown in FIG. 6. In certain embodiments, the conductive material 71 is a metal or metals. For example, the conductive material 71 may be or include Ru, W, Mo, other suitable metals, and/or a combination thereof.

At operation S922, the method 900 (FIG. 1) forms a conductive via 70 from the conductive material 71 in the opening 58 as shown in FIG. 7. For example, a chemical mechanical planarization (CMP) process may be performed to remove the overburden portion 72 of the conductive material 71.

At operation S924, the method 900 (FIG. 1) forms a dielectric layer 80 over the dielectric layer 50 and the conductive via 70. In certain embodiments, the dielectric layer 80 is a low-K dielectric layer. For example, the dielectric layer 50 may have a K value of from 2 to 3.

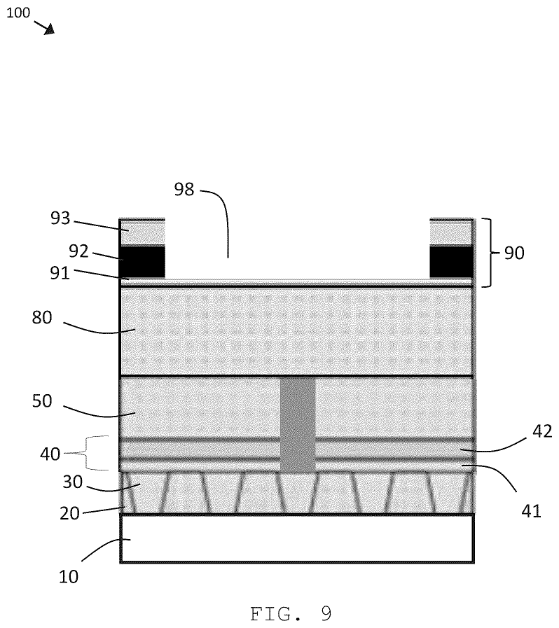

At operation S926, the method 900 (FIG. 1) forms a hard mask 90 over the dielectric layer 80, as shown in FIG. 8. The hard mask 90 may include multiple layers, such as a bottom layer 91, a middle layer 92, and a top layer 93.

In some embodiments, the bottom layer 91 may be formed from or includes non-metal-containing dielectric such as silicon oxide, which may be formed, for example, using tetra ethyl ortho silicate (TEOS) as a precursor. For example, the bottom layer 91 may be SiO₂, SiOC, and/or other suitable materials.

In some embodiments, the middle layer 92 may be formed from or includes metal. For example, the middle layer 92 may be or include layers of titanium, tungsten, or ruthenium. The metal in middle layer 92 may be elemental (not a compound) or in the form of a metal compound. For example, metal hard mask layer may be an elemental titanium layer, tungsten layer, or ruthenium layer, a titanium alloy layer, tungsten alloy layer, or ruthenium alloy layer. Metal hard mask layer may also be a compound layer of the metal and other elements such as carbon, nitrogen, or combinations thereof. For example, middle layer 92 may include TiN, WC, and/or other suitable materials.

In certain embodiments, the middle layer 92 is a ceramic compound. For example, middle layer 92 may be formed from or include boron nitride (BN).

In some embodiments, the top layer 93 may be formed from or includes non-metal-containing dielectric such as silicon oxide, which may be formed, for example, using tetra ethyl ortho silicate (TEOS) as a precursor. For example, the top layer 93 may be SiO₂, SiOC, and/or other suitable materials.

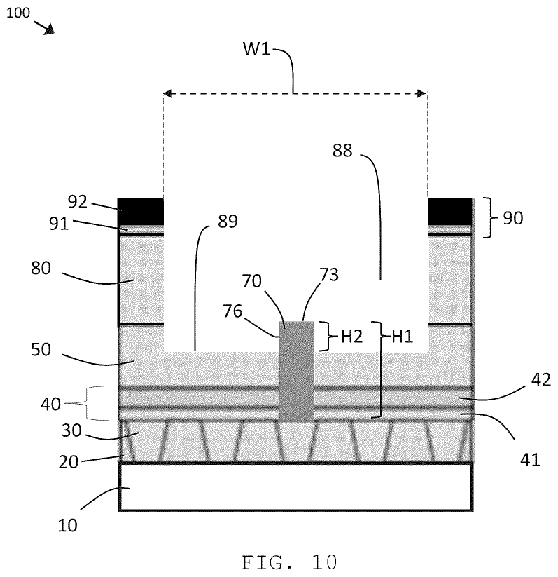

At operation S928, the method 900 (FIG. 1) patterns the hard mask 90 to form an opening 98, as shown in FIG. 9. For example, an etching process may be performed to etch the top layer 93 and the middle layer 92. The bottom layer 91 may be used as an etch stop layer. Top layer 93 and middle layer 92 may be etched using different etching chemicals, and each may be etched using an anisotropic etching process (a dry etching process) or an isotropic etching process. For example, top layer 93 may be etched using the mixture of NF₃ and NH₃ gases or a mixture of HF and NH₃ gases when dry etching is used, or HF solution when wet etching is used. Metal hard mask layer 92 may be etched using gases comprising BCl₃, Cl₂, CF₄, CHF₃, NF₃, O₂, Ar, etc. or combinations thereof when dry etching is used, or phosphoric acid solution when wet etching is used.

At operation S930, the method 900 (FIG. 1) performs an etch process to etch the dielectric layers 80 and 50 through the opening 98 to form a trench 88, as shown in FIG. 10. The etch process may remove top layer 93. As shown, metal middle layer 92 is not etched by the etch process. Through opening 98, the etch process removes bottom layer 91 and dielectric layer 80, and etches into dielectric layer 50.

As shown, in operation S930, the etch process does not land on an etch stop layer. Rather, operation S930 includes control of loading and adjustment of selectivity ratio to slightly eat into the low-K dielectric 50 to form trench 88 with a trench bottom 89 formed by the dielectric layer 50.

As shown in FIG. 10, the etch process is controlled to extend to a trench bottom surface 89 that is located below the upper surface 73 of the conductive via 70. Specifically, the trench bottom surface 89 is located between the height of the conductive via upper surface 73 and the substrate 10. Thus, a side surface 76 of the conductive via 70 is uncovered and extends from the trench bottom surface 89 to the conductive via upper surface 73.

As shown, the conductive via 70 has a height H1 from a bottom end contacting the conductive structure 30 to the conductive via upper surface 73. Further, the side surface has a height H2 from the trench bottom surface 89 to the conductive via upper surface 73. In certain embodiments, the ratio of height H2 to height H1 is at least 0.05 to 1, such as at least 0.1 to 1; at least 0.15 to 1; at least 0.2 to 1; at least 0.25 to 1; at least 0.3 to 1; at least 0.35 to 1; at least 0.4 to 1; at least 0.45 to 1; at least 0.5 to 1; at least 0.55 to 1; at least 0.6 to 1; at least 0.65 to 1; at least 0.7 to 1; at least 0.75 to 1; at least 0.8 to 1; at least 0.85 to 1; at least 0.9 to 1; or at least 0.95 to 1. In certain embodiments, the ratio of height H2 to height H1 is at most 0.05 to 1, at most 0.1 to 1; at most 0.15 to 1; at most 0.2 to 1; at most 0.25 to 1; at most 0.3 to 1; at most 0.35 to 1; at most 0.4 to 1; at most 0.45 to 1; at most 0.5 to 1; at most 0.55 to 1; at most 0.6 to 1; at most 0.65 to 1; at most 0.7 to 1; at most 0.75 to 1; at most 0.8 to 1; at most 0.85 to 1; at most 0.9 to 1; or at most 0.95 to 1. In certain embodiments, the ratio of height H2 to height H1 provides for increased contact area between the conductive via and later formed conductive trench 110 while facilitating processing.

Height H2 may be from 10 to 100 Anstrom (Å). For example, height H2 may be at least 10 Å, at least 15 Å, at least 20 Å, at least 25 Å, at least 30 Å, at least 35 Å, at least 40 Å, at least 45 Å, at least 50 Å, at least 55 Å, at least 60 Å, at least 65 Å, at least 70 Å, at least 75 Å, at least 80 Å, at least 85 Å, at least 90 Å, or at least 95 Å. Further, height H2 may be at most 10 Å, at most 15 Å, at most 20 Å, at most 25 Å, at most 30 Å, at most 35 Å, at most 40 Å, at most 45 Å, at most 50 Å, at most 55 Å, at most 60 Å, at most 65 Å, at most 70 Å, at most 75 Å, at most 80 Å, at most 85 Å, at most 90 Å, at most 95 Å, or at most 100 Å. In certain embodiments, height H2 is from 20 to 60 Å, such as from 20 to 40 Å.

As shown in FIG. 10, trench 88 has a lateral width W1. Method 900 may form trenches 88 having different widths W1 during a same process, i.e., narrower trenches 88 with a smaller width W1 and wider trenches 88 with a larger width W1. It is noted that for narrower trenches 88 and wider trenches 88 may be formed with different heights H2 of the conductive vias 70 uncovered. For example, a difference in heights H2 between different trenches 88 may be from 20 to 40 Å. Such trench depth loading may result from the type of processing performed.

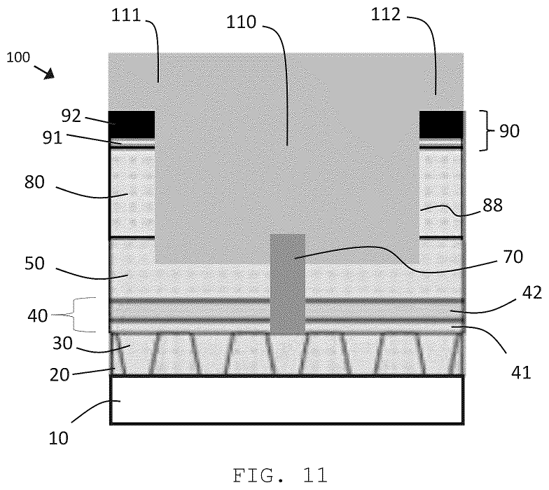

At operation S932, the method 900 (FIG. 1) deposits a conductive material 111 to fill the trench 88 as shown in FIG. 11. In certain embodiments, the conductive material 111 is a metal or metals. For example, the conductive material 111 may be or include Cu, Ru, W, Mo, other suitable metals, and/or a combination thereof.

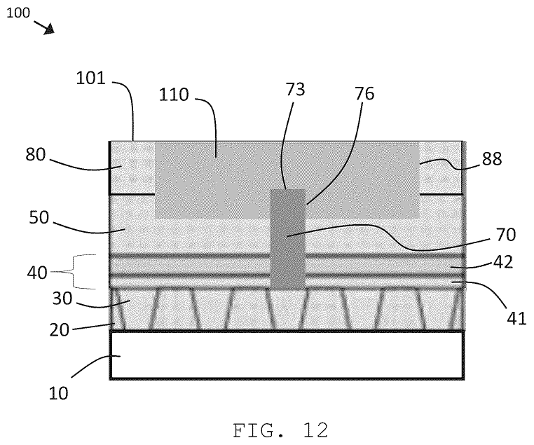

At operation S934, the method 900 (FIG. 1) forms a conductive trench 110 from the conductive material 111 in the trench 88 as shown in FIG. 12. For example, a chemical mechanical planarization (CMP) process may be performed to remove the overburden portion 112 of the conductive material 111. As a result, the structure 100 is formed with an upper surface 101 form by the dielectric layer 80 and the conductive trench 110.

Method 900 (FIG. 1) may continue with further processing at operation S936. For example additional dielectric layers and metal layers may be deposited and etched to form a conductive interconnect over the conductive trench 110. The further processing may include other back-end-of-line processing such as passivation and packaging and other processes.

As shown, in structure 100, the contact area between the conductive via 70 and the conductive trench 110 is not limited to the conductive via upper surface 73. Rather, the conductive via 70 contacts the conductive trench 110 along the conductive via upper surface 73 and along the conductive via side surface 76 for height H2. As a result, contact resistance between the conductive via 70 and the conductive trench 110 may be reduced.

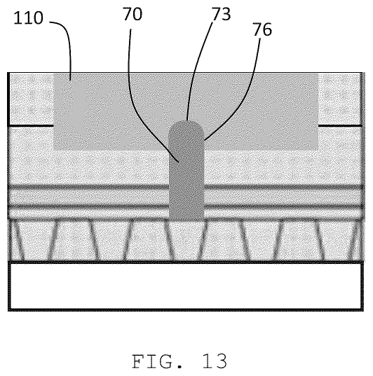

FIG. 13 illustrates that, in the structure 100 of FIG. 12, the conductive via upper surface 73 may be rounded. Rounding the corner between the side surface 76 and the upper surface 73 may further increase contact area between the conductive via 70 and the conductive trench 110.

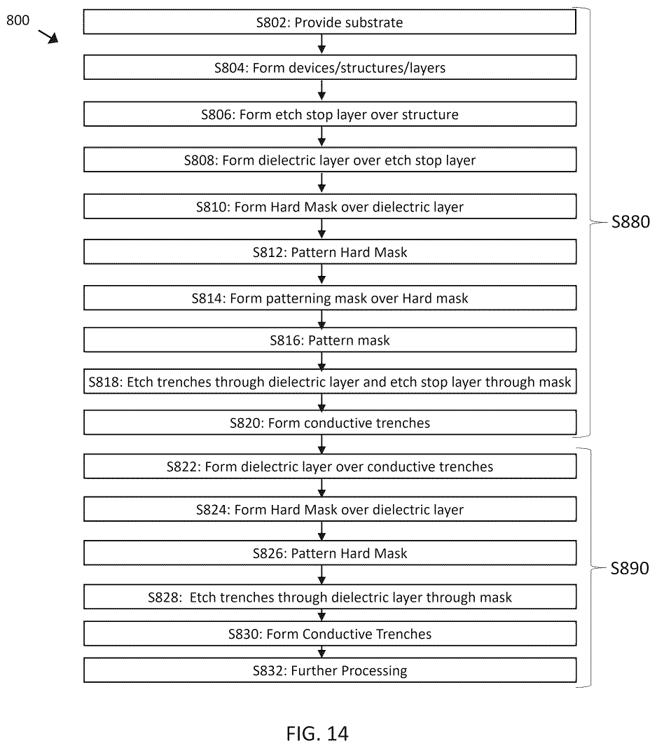

FIGS. 14-24 illustrate another embodiment in which a Dual-Damascene and Single Damascene (DDSD) process is used.

Referring to FIG. 14, a method 800 for forming a semiconductor structure 100 is illustrated in a flow chart, according to various aspects of the present disclosure.

FIG. 14 is described in conjunction with FIGS. 15-23, which illustrate a semiconductor device or structure 100 at various stages of fabrication in accordance with some embodiments of the present disclosure of the method 800. The method 800 is merely an example, and is not intended to limit the present disclosure beyond what is explicitly recited in the claims. Additional steps may be provided before, during, and after method 800, and some of the steps described can be moved, replaced, or eliminated for additional embodiments of method 800. Additional features may be added in the semiconductor device depicted in the Figures and some of the features described below can be replaced, modified, or eliminated in other embodiments of the semiconductor device.

As with other method embodiments and exemplary devices discussed herein, it is understood that parts of the semiconductor structure 100 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 800, including any descriptions given with reference to the Figures, as with the remainder of the method and exemplary figures provided in this disclosure, are merely exemplary and are not intended to be limiting beyond what is specifically recited in the claims that follow.

At operation S802, the method 800 (FIG. 14) provides a substrate 10, as shown in FIG. 15. In some embodiments, the substrate 10 may be a semiconductor substrate such as a silicon (Si) substrate. The substrate 10 may include various layers, including conductive or insulating layers formed on a semiconductor substrate. The substrate 10 may include various doping configurations depending on design requirements as is known in the art. For example, different doping profiles (e.g., p-well, n-well) may be formed on the substrate 10 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 10 includes a single crystalline semiconductor layer on at least its surface portion. The substrate 10 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 10 may include a compound semiconductor and/or an alloy semiconductor. In the illustrated embodiment, the substrate 10 is made of crystalline Si.

At operation S804, the method 800 (FIG. 14) may form active devices, such as transistors, etc., passive devices, such as resistors and others, interconnect structures, and insulating layers on and/or in substrate 10.

At operation S806, the method 800 (FIG. 14) may form an etch stop layer 140 over the substrate 10, as shown in FIG. 15. For example, operation S806 may include forming a first etch stop layer 141 over the substrate 10. In certain embodiments, the first etch stop layer 141 may be formed from or includes layers of AlON, AlOx, AlON, SiCN, and/or other suitable materials. Also, operation S810 may include forming a second etch stop layer 142 over the first etch stop layer 141. In certain embodiments, the second etch stop layer 142 may be formed from or include layers of SiC, SiOx, SiOC, SiON, and/or other suitable materials.

At operation S808, the method 800 (FIG. 14) forms a dielectric layer 150 over the etch stop layer 140, as shown in FIG. 15. In certain embodiments, the dielectric layer 150 is a low-K dielectric layer. For example, the dielectric layer 150 may have a K value of from 2 to 3.

At operation S810, the method 800 (FIG. 14) forms a hard mask 190 over the dielectric layer 150, as shown in FIG. 15. The hard mask 190 may include multiple layers, such as a bottom layer 191, a middle layer 192, and a top layer 193.

In some embodiments, the bottom layer 191 may be formed from or includes non-metal-containing dielectric such as silicon oxide, which may be formed, for example, using tetra ethyl ortho silicate (TEOS) as a precursor. For example, the bottom layer 191 may be SiO₂, SiOC, and/or other suitable materials.

In some embodiments, the middle layer 192 may be formed from or includes metal. For example, the middle layer 192 may be or include layers of titanium, tungsten, or ruthenium. The metal in middle layer 192 may be elemental (not a compound) or in the form of a metal compound. For example, metal hard mask layer may be an elemental titanium layer, tungsten layer, or ruthenium layer, a titanium alloy layer, tungsten alloy layer, or ruthenium alloy layer. Metal hard mask layer may also be a compound layer of the metal and other elements such as carbon, nitrogen, or combinations thereof. For example, middle layer 192 may include TiN, WC, and/or other suitable materials.

In certain embodiments, the middle layer 192 is a ceramic compound. For example, middle layer 192 may be formed from or include boron nitride (BN).

In some embodiments, the top layer 193 may be formed from or includes non-metal-containing dielectric such as silicon oxide, which may be formed, for example, using tetra ethyl ortho silicate (TEOS) as a precursor. For example, the top layer 193 may be SiO₂, SiOC, and/or other suitable materials.

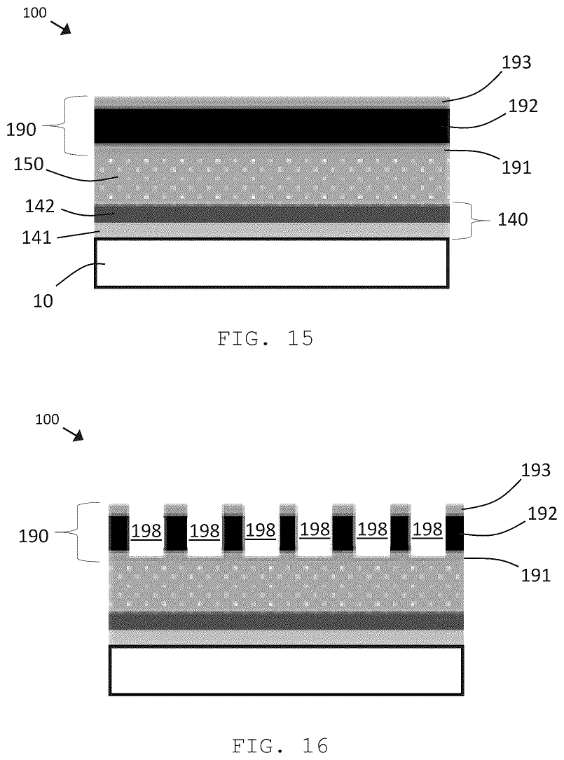

At operation S812, the method 800 (FIG. 14) patterns the hard mask 190 to form openings 198, as shown in FIG. 16 For example, an etching process may be performed to etch the top layer 193 and the middle layer 192. The bottom layer 191 may be used as an etch stop layer. Top layer 193 and middle layer 192 may be etched using different etching chemicals, and each may be etched using an anisotropic etching process (a dry etching process) or an isotropic etching process. For example, top layer 193 may be etched using the mixture of NF₃ and NH₃ gases or a mixture of HF and NH₃ gases when dry etching is used, or HF solution when wet etching is used. Metal hard mask layer 192 may be etched using gases comprising BCl₃, Cl₂, CF₄, CHF₃, NF₃, O₂, Ar, etc. or combinations thereof when dry etching is used, or phosphoric acid solution when wet etching is used.

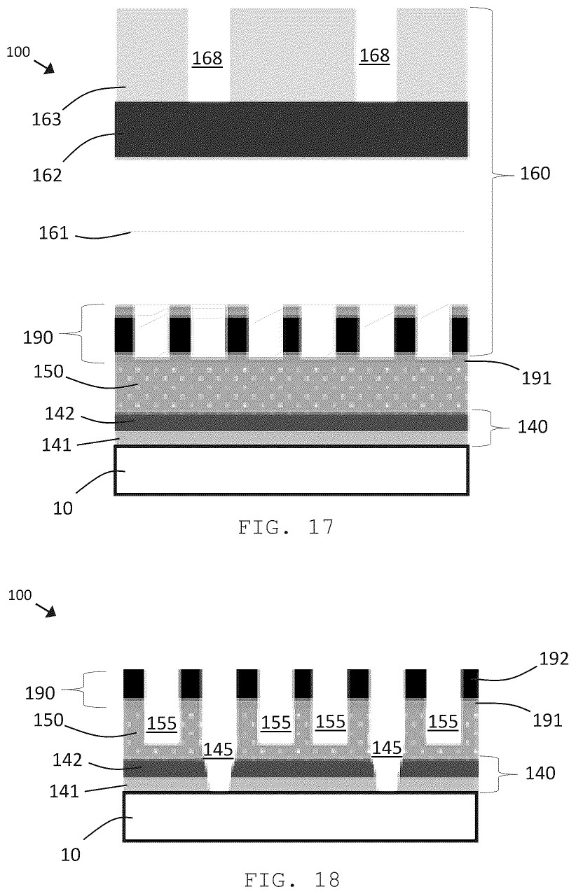

At operation S814, the method 800 (FIG. 14) forms a patterning mask 160 over the structure 100, as shown in FIG. 17.

The patterning mask 160 may include multiple layers, such as a bottom layer 161, a middle layer 162, and a top layer 163. In some embodiments, the bottom layer 161 is a bottom anti-reflective coating (BARC). The BARC may provide for absorption of radiation incident to the substrate during photolithography processes, including exposure of an overlying photoresist layer. In some embodiments, the middle layer 162 includes a reflective multilayer structure. In some embodiments, the top layer 163 is a photosensitive mask (e.g., photoresist).

The photoresist may be positive-tone or negative-tone resist. In an embodiment, the photoresist is chemical amplified photoresist (CAR). The photoresist may include a polymer, a photoacid generator (PAG), which provides the solubility change to the developer, a solvent, and/or other suitable compositions. The photoresist may be formed by processes such as coating (e.g., spin-on coating) and soft baking.

At operation S816, the method 800 (FIG. 14) patterns the photoresist layer 163, as shown in FIG. 17, to form openings 168. For example, the method may use various and/or varying wavelengths of radiation to expose the energy-sensitive photoresist layer. In an embodiment, the mask is irradiated using ultraviolet (UV) radiation or extreme ultraviolet (EUV) radiation. The radiation beam may additionally or alternatively include other radiation beams such as ion beam, x-ray, extreme ultraviolet, deep ultraviolet, and other proper radiation energy. In an example, the photoresist includes photo-acid generator (PAG) that generates acid during the exposure process thus changing the solubility of the exposed/non-exposed material. Lithography processes include immersion lithography, photolithography, optical lithography and/or other patterning methods which may transfer a pattern onto the photosensitive layer. Patterning may further include a post-exposure bake (PEB) process. During the baking process, the photoresist layer is provided at an elevated temperature. This may allow more acid to be generated from the photo-generated acids through a chemical amplification process. Further, patterning may include developing the photoresist layer. The developing may form a patterned photoresist layer including a plurality of masking elements or features. During the developing process, a developing solution is applied to the photoresist layer. In one embodiment, the photoresist material that was exposed to the radiation is removed by the developing solution (developer). However, implementing a negative-tone resist is also possible. The developer or developing solution may be a positive tone developer or negative tone developer. One exemplary developer is aqueous tetramethylammonium hydroxide (TMAH).

At operation S818, the method 800 (FIG. 14) performs an etch process to etch the structure 100, as shown in FIG. 18. Specifically, the etch process etches through openings 168 to form trenches 145 that extend through etch stop layer 140 into contact with substrate 10. As shown, trenches 145 do not land on a contact etch stop layer. As further shown, the trenches 145 may a tapered profile, i.e., a larger critical dimension at a height above the substrate 10, reducing to a minimum critical dimension at the substrate 10.

Further, the etch process removes the patterning mask 160 and top layer 193 of hard mask 190. As shown, the etch process etches the bottom layer 191 of the hard mask 190 not covered by the metal middle layer 192, and continues to etch into the dielectric layer 150, forming trenches 155 that stop within the dielectric layer 150. As shown, trenches 155 do not land on an etch stop layer.

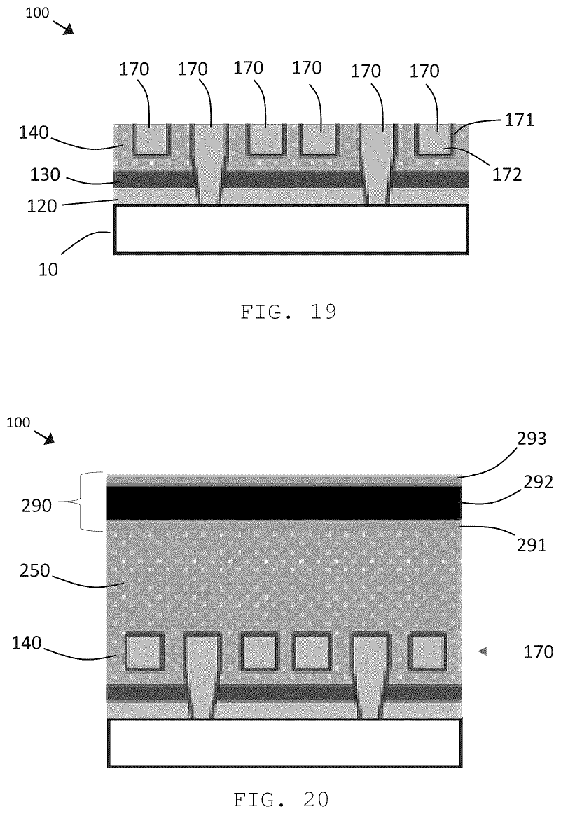

At operation S820, the method 800 (FIG. 14) forms conductive trenches 170 in trenches 145 and trenches 155, as shown in FIG. 19. For example, a trench barrier liner 171 may be deposited along the surfaces of the trenches 145 and trenches 155. The trench liner 171 may be formed from tantalum nitride (TaN), cobalt (Co), ruthenium (Ru), manganese (Mn), or other suitable materials or combinations thereof. The trench liner 171 may have a thickness of from 0 to 30 Angstrom.

Further, operation S818 may include filling the trenches 145 and trenches 155 with a conductive fill material 172. For example, the conductive fill material 172 may be copper (Cu), tungsten (W), ruthenium (Ru), another suitable material, or combinations thereof.

Operation S820 may include performing a chemical mechanical planarization (CMP) process to remove any overburden portion of trench liner 171 and conductive fill material 172 to form the conductive trenches 170 in the trenches 145 and 155, as shown in FIG. 19.

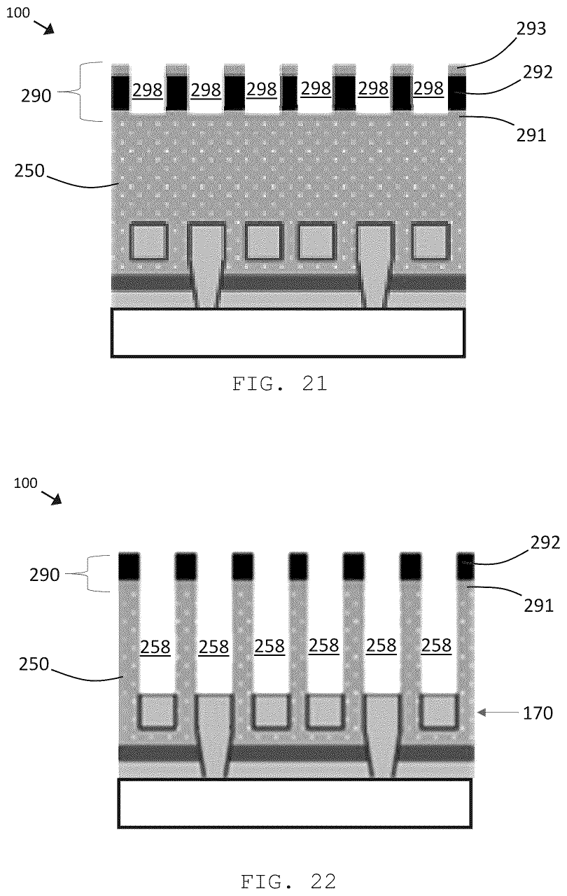

At operation S822, the method 800 (FIG. 14) forms a dielectric layer 250 over the structure 100, as shown in FIG. 20. In certain embodiments, the dielectric layer 250 is a low-K dielectric layer. For example, the dielectric layer 250 may have a K value of from 2 to 3.

At operation S824, the method 800 (FIG. 14) forms a hard mask 290 over the dielectric layer 250, as shown in FIG. 20. The hard mask 290 may include multiple layers, such as a bottom layer 291, a middle layer 292, and a top layer 293.

In some embodiments, the bottom layer 291 may be formed from or includes non-metal-containing dielectric such as silicon oxide, which may be formed, for example, using tetra ethyl ortho silicate (TEOS) as a precursor. For example, the bottom layer 291 may be SiO₂, SiOC, and/or other suitable materials.

In some embodiments, the middle layer 292 may be formed from or includes metal. For example, the middle layer 292 may be or include layers of titanium, tungsten, or ruthenium. The metal in middle layer 292 may be elemental (not a compound) or in the form of a metal compound. For example, metal hard mask layer may be an elemental titanium layer, tungsten layer, or ruthenium layer, a titanium alloy layer, tungsten alloy layer, or ruthenium alloy layer. Metal hard mask layer may also be a compound layer of the metal and other elements such as carbon, nitrogen, or combinations thereof. For example, middle layer 292 may include TiN, WC, and/or other suitable materials.

In certain embodiments, the middle layer 292 is a ceramic compound. For example, middle layer 292 may be formed from or include boron nitride (BN).

In some embodiments, the top layer 293 may be formed from or includes non-metal-containing dielectric such as silicon oxide, which may be formed, for example, using tetra ethyl ortho silicate (TEOS) as a precursor. For example, the top layer 293 may be SiO₂, SiOC, and/or other suitable materials.

At operation S826, the method 800 (FIG. 14) patterns the hard mask 290 to form openings 298, as shown in FIG. 21. For example, an etching process may be performed to etch the top layer 293 and the middle layer 292. The bottom layer 291 may be used as an etch stop layer. Top layer 293 and middle layer 292 may be etched using different etching chemicals, and each may be etched using an anisotropic etching process (a dry etching process) or an isotropic etching process. For example, top layer 293 may be etched using the mixture of NF₃ and NH₃ gases or a mixture of HF and NH₃ gases when dry etching is used, or HF solution when wet etching is used. Metal hard mask layer 292 may be etched using gases comprising BCl₃, Cl₂, CF₄, CHF₃, NF₃, O₂, Ar, etc. or combinations thereof when dry etching is used, or phosphoric acid solution when wet etching is used.

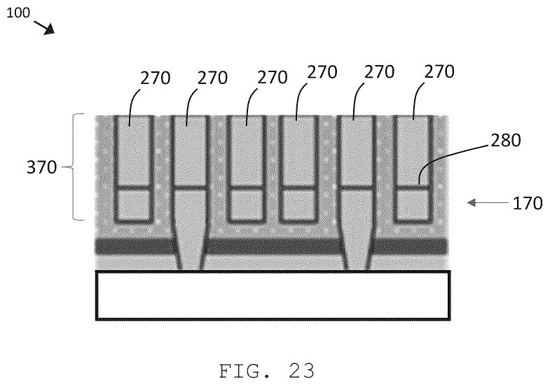

At operation S828, the method 800 (FIG. 14) performs an etch process to etch the dielectric layer 250 through the openings 298 in the hard mask 190 to form trenches 258, as shown in FIG. 22. The etch process may remove top layer 293. As shown, metal middle layer 292 is not etched by the etch process. Through openings 298, the etch process removes bottom layer 291 and dielectric layer 250, and lands on the conductive trenches 170.

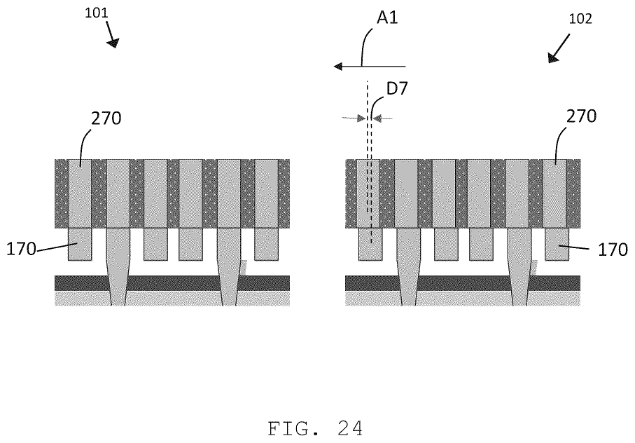

At operation S830, the method 800 (FIG. 14) forms conductive trenches 270 in trenches 258, as shown in FIG. 23. For example, a trench barrier liner 271 may be deposited along the surfaces of the trenches 258. The trench liner 271 may be formed from tantalum nitride (TaN), cobalt (Co), ruthenium (Ru), manganese (Mn), or other suitable materials or combinations thereof. The trench liner 271 may have a thickness of from 0 to 30 Angstrom.

Further, operation S830 may include filling the trenches 258 with a conductive fill material 272. For example, the conductive fill material 272 may be copper (Cu), tungsten (W), ruthenium (Ru), another suitable material, or combinations thereof.

Operation S830 may include performing a chemical mechanical planarization (CMP) process to remove any overburden portion of trench liner 271 and conductive fill material 272 to form the conductive trenches 270 in the trenches 258, as shown in FIG. 23. As shown, the conductive trenches 170 and conductive trenches 270 contact one another at an interface 280. As further shown, the conductive trenches 170 and conductive trenches 270 form interconnect structures 370.

Method 800 (FIG. 14) may continue with further processing at operation S832. For example additional dielectric layers and metal layers may be deposited and etched to form a conductive interconnects over the conductive trenches 270. The further processing may include other back-end-of-line processing such as passivation and packaging and other processes.

As shown in FIG. 14, operations S802 through S820 may constitute a dual damascene process S880, and subsequent operations S822 through S832 may constitute a single damascene process S890. Thus, method 800 is a combined Dual-Damascene and Single Damascene (DDSD) process.

Power, performance, and area (PPA) has been a key indicator of competitiveness in semiconductor processes. Traditional back-end-of-line (BEOL) dual-damascene interconnects offer many performance advantages, such as (1) the benefits of low resistance with Cu-filling, (2) fewer interfaces to reduce parasitic capacitance, and (3) a shorter process flow. Because of these advantages, Cu dual-damascene has been the main manufacturing method for back-end interconnects in the past decade. As dimensions shrink, dual-damascene interconnect faces numerous challenges, including the need for more constrained design rules which can lead to a decrease in routing efficiency. However, in single-damascene processing, the trench and via are fabricated separately, and several major issues may arise: (1) performance loss due to the high-k etch-stop layer in trench and via interface, (2) an increase in resistance due to the small trench to via contact area. These factors may all contribute to additional RC delay penalties during the process change.

FIG. 24 illustrates two structures 101 and 102 formed according to the method 800. In structure 101, the conductive trenches 270 are properly aligned with the underlying conductive trenches 170. In structure 102, the upper conductive trenches 270 are misaligned in the direction of arrow A1 by a distance D7. For example, the overlay shift may be a distance D7 of from 2 to 3 nanometers.

Method 800 provides the benefits of a dual-damascene process, including the self-aligned vias (SAV), low resistance/capacitance architecture design, while also incorporating aspect-ratio design similar to single-damascene processing. Method 800 may simultaneously achieve a good process window, less penalty on resistive-capacitive (RC) delay, and better overlay (OVL) controllability. In summary, the Dual-Damascene and Single Damascene (DDSD) process may produce the traditional dual-damascene architecture but with the process window of single damascene processing.

In certain embodiments, the design logic of Dual-Damascene and Single Damascene (DDSD) may minimize the aspect ratio of the first dual-damascene process, in order to maximize the window of space damage/under-etch and metal gap-filling. In addition, the first CMP process may polish away the damaged space, keeping the space relatively wide to reduce some leakage concerns. Following that, the second single-damascene process can directly interface with the lower dual damascene (DD) structure. Due to the trench to trench interfacing, there is no need for an additional etch stop layer to cause capacitance loss. Furthermore, due to the use of a single damascene trench, the space is not damaged by the via, there is no risk of tiger-tooth issues for the via above, and the design rule constraints can be relaxed.

In certain embodiments, method 800 provides a larger process window and a low RC flow design, in order to address the challenges faced by dual-damascene and single-damascene technologies.

The advantages of dual-damascene, especially the benefits of self-aligned vias (SAV) for overlay (OVL) control and the advantages of trench/via all-in-one copper filling are known. However, as dimensions continue to shrink, the challenges in the process become severe. For example, as the Via to trench OVL is confined by the metal hard mask, when the trench CD is reduced to a certain extent, (1) the space of the trench will start to be damaged by the via, (2) the via may be under etched due to the narrow trench width, and (3) small trench size with high aspect ratio can also easily cause Cu gap-filling to result in pits.

In method 800, the upper and lower layers 250/150 of low-K dielectric may be a bi-layer film scheme. Further, in method 800, no trench is etched to land on an etch stop layer, i.e., no trench has a trench bottom formed by an etch stop layer. In certain embodiments, a barrier liner containing TaN/Co/Mn/Ru may be provided in the trenches. Additionally, the two layers of trenches, i.e., the trenches formed by DD and the trenches formed by SD, may be designed with different dimensions for OVL consideration. Further, in method 800 the trenches 145 formed through etch stop layer 140 is copper gap-filling and has a taper via profile.

In one embodiment, a method is provided. The method includes forming a conductive via over a substrate; forming a dielectric layer over the conductive via and the substrate; patterning a mask over the dielectric layer; performing an etch process to etch the dielectric layer through the mask to form a trench over the conductive via, wherein the trench extends to a trench bottom formed by the dielectric layer, and wherein the trench bottom intersects the conductive via; and forming a conductive structure in the trench.

In some embodiments of the method, the conductive via extends from a bottom surface to an uppermost surface and has a vertical height H1 therebetween; the trench bottom is distanced from the uppermost surface by a vertical height H2; and a ratio of height H2 to height H1 is at least 0.05 to 1.

In some embodiments of the method, the conductive via has an upper surface and a side surface extending from the upper surface to the trench bottom; and the conductive structure contacts the upper surface and the side surface of the conductive via.

In some embodiments of the method, the conductive via comprises Ru, W, and/or Mo; and the conductive structure comprises Cu, Ru, and/or W.

In some embodiments of the method, the upper surface is distanced from the trench bottom by a distance of at least 20 Angstrom.

In some embodiments of the method, the conductive via has a rounded upper surface.

In some embodiments, the method further includes forming an etch stop layer over the substrate, wherein the dielectric layer is formed over the etch stop layer, wherein the trench is a first trench; performing the etch process comprises etching the dielectric layer through the mask to form a second trench, and the second trench extends through the etch stop layer and lands on the substrate.

In some embodiments of the method, forming the conductive structure in the trench comprises forming the first conductive structure in the first trench and forming a second conductive structure in the second trench.

In some embodiments of the method, forming the first conductive structure in the first trench and forming a second conductive structure in the second trench comprises forming a barrier liner in each trench and forming a conductive metal fill over the barrier liner in each trench.

In some embodiments, the method further includes forming a second dielectric layer over the first conductive structure and the second conductive structure; etching the second dielectric layer to form a first upper trench over the first conductive structure and a second upper trench over the second conductive structure; and forming a first upper conductive structure in the first upper trench and forming a second upper conductive structure in the second upper trench.

In another embodiment, a semiconductor structure is provided and includes a semiconductor substrate; a conductive via extending upward from the substrate to an upper surface; and a conductive trench located over the conductive via, wherein the upper surface of the conductive via is encapsulated by the conductive trench.

In certain embodiments, the conductive via has a side surface; and an upper portion of the side surface contacts the conductive trench.

In certain embodiments, a lower portion of the side surface contacts a dielectric material located between the conductive trench and the substrate.

In certain embodiments, the upper surface of the conductive via is rounded.

In certain embodiments, the upper surface of the conductive via is distanced from the trench bottom by a distance of at least 20 Angstrom.

In another embodiment, a semiconductor structure is provided and includes a semiconductor substrate; an etch stop layer located over the substrate; a lower dielectric layer located over the etch stop layer; a first lower conductive via extending through the first dielectric layer and etch stop layer into contact with the semiconductor substrate; and a second lower conductive via in the first dielectric layer, wherein the second lower conductive is separated from the etch stop layer by the first dielectric layer.

In certain embodiments, the semiconductor structure further includes an upper dielectric layer located over the lower dielectric layer, the first lower conductive via and the second lower conductive via; a first upper conductive trench extending through the upper dielectric layer, located over and aligned with the first lower conductive via; and a second upper conductive trench extending through the upper dielectric layer, located over and aligned with the second lower conductive via.

In certain embodiments, at least the lower conductive vias comprise a barrier liner and a fill material located over the barrier liner.

In certain embodiments, the upper conductive trenches comprises Cu, Ru, and/or W.

In certain embodiments, the lower conductive vias comprise Ru, W, and/or Mo.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a conductive via over a substrate;
forming a dielectric layer over the conductive via and the substrate;
patterning a mask over the dielectric layer;
performing an etch process to etch the dielectric layer through the mask to form a trench over the conductive via, wherein the trench extends to a trench bottom formed by the dielectric layer, and wherein the trench bottom intersects the conductive via; and
forming a conductive structure in the trench.

2. The method of claim 1, wherein:
the conductive via has an upper surface and a side surface extending from the upper surface to the trench bottom; and
the conductive structure contacts the upper surface and the side surface of the conductive via.

3. The method of claim 2, wherein:
the conductive via comprises Ru, W, and/or Mo; and
the conductive structure comprises Cu, Ru, and/or W.

4. The method of claim 2, wherein the upper surface is distanced from the trench bottom by a distance of at least 20 Angstrom.

5. The method of claim 2, the conductive via has a rounded upper surface.

6. The method of claim 1, further comprising forming an etch stop layer over the substrate, wherein the dielectric layer is formed over the etch stop layer, wherein:
the trench is a first trench;
performing the etch process comprises etching the dielectric layer through the mask to form a second trench, and
the second trench extends through the etch stop layer and lands on the substrate.

7. The method of claim 6, wherein:
forming the conductive structure in the trench comprises forming the first conductive structure in the first trench and forming a second conductive structure in the second trench.

8. The method of claim 7, wherein forming the first conductive structure in the first trench and forming a second conductive structure in the second trench comprises forming a barrier liner in each trench and forming a conductive metal fill over the barrier liner in each trench.

9. The method of claim 8, further comprising:
forming a second dielectric layer over the first conductive structure and the second conductive structure;
etching the second dielectric layer to form a first upper trench over the first conductive structure and a second upper trench over the second conductive structure; and
forming a first upper conductive structure in the first upper trench and forming a second upper conductive structure in the second upper trench.

10. The method of claim 1, wherein
the conductive via extends from a bottom surface to an uppermost surface and has a vertical height H1 therebetween;
the trench bottom is distanced from the uppermost surface by a vertical height H2; and
a ratio of height H2 to height H1 is at least 0.05 to 1.

11. A semiconductor structure comprising:
a semiconductor substrate;
a conductive via extending upward from the substrate to an upper surface; and
a conductive trench located over the conductive via, wherein the upper surface of the conductive via is encapsulated by the conductive trench.

12. The semiconductor structure of claim 11, wherein:
the conductive via has a side surface; and
an upper portion of the side surface contacts the conductive trench.

13. The semiconductor structure of claim 12, wherein a lower portion of the side surface contacts a dielectric material located between the conductive trench and the substrate.

14. The semiconductor structure of claim 13, wherein the upper surface of the conductive via is rounded.

15. The semiconductor structure of claim 14, wherein the upper surface of the conductive via is distanced from the trench bottom by a distance of at least 20 Angstrom.

16. A semiconductor structure comprising:
a semiconductor substrate;
an etch stop layer located over the substrate;
a lower dielectric layer located over the etch stop layer;
a first lower conductive via extending through the first dielectric layer and etch stop layer into contact with the semiconductor substrate; and
a second lower conductive via in the first dielectric layer, wherein the second lower conductive is separated from the etch stop layer by the first dielectric layer.

17. The semiconductor structure of claim 16, further comprising:
an upper dielectric layer located over the lower dielectric layer, the first lower conductive via and the second lower conductive via;
a first upper conductive trench extending through the upper dielectric layer, located over and aligned with the first lower conductive via; and
a second upper conductive trench extending through the upper dielectric layer, located over and aligned with the second lower conductive via.

18. The semiconductor structure of claim 17, wherein at least the lower conductive vias comprise a barrier liner and a fill material located over the barrier liner.

19. The semiconductor structure of claim 18, wherein the upper conductive trenches comprises Cu, Ru, and/or W.

20. The semiconductor structure of claim 19, wherein the lower conductive vias comprise Ru, W, and/or Mo.
